(19) United States
(12) Patent Application Publication
(10) Pub. No.: US 2021/0181562 A1
(43) Pub. Date: Jun. 17, 2021

(54) AIR SPECIES BARRIERS IN LIQUID CRYSTAL DISPLAY DEVICES

(71) Applicant: Flexenable Limited, Cambridge (GB)

(72) Inventor: Barry Wild, Cambridge (GB)

(21) Appl. No.: 16/758,954

(22) PCT Filed: Oct. 22, 2018
(86) PCT No.: PCT/EP2018/078911

§ 371 Date: Apr. 24, 2020

(30) Foreign Application Priority Data
Oct. 27, 2017 (GB) 1717725.4

(51) Int. Cl. G02F 1/1368; H01L 27/28

(52) U.S. Cl. CPC G02F 1/13685; G02F 1/136227; G02F 2202/022; H01L 27/283

(57) ABSTRACT

A device, comprising: a liquid crystal cell comprising liquid crystal material; a stack of layers, including one or more organic polymer semiconductor layers, for electrically controlling one or more optical properties of the liquid crystal material; first and second air species barriers between which both said liquid crystal material and said one or more organic polymer semiconductor layers are located; and a third air species barrier between said liquid crystal material and said one or more organic polymer semiconductor layers; wherein the first and second air species barriers exhibit substantially different transmission rates under the same conditions for at least one air species.

The performance of at least both (a) the liquid crystal material of a liquid crystal display (LCD) device and (b) the organic polymer semiconductor in the stack of layers that defines electrical circuitry for controlling one or more optical properties of the liquid crystal material, is known to be negatively affected by species present in air; and it is known to encapsulate both these elements together between a pair of moisture barriers.

The inventors for the present application have conducted work into further improving the performance of OLCD display devices, particularly in relation to the protection of the LC material and the organic polymer semiconductor against the damaging effects of air species.

There is hereby provided a device, comprising: a liquid crystal cell comprising liquid crystal material; a stack of layers, including one or more organic polymer semiconductor layers, for electrically controlling one or more optical properties of the liquid crystal material; first and second air species barriers between which both said liquid crystal material and said one or more organic polymer semiconductor layers are located; and a third air species barrier between said liquid crystal material and said one or more organic polymer semiconductor layers; wherein the first and second air species barriers exhibit substantially different transmission rates under the same conditions for at least one air species.

According to one embodiment, said liquid crystal material is located between said first and third air species barriers, and wherein said first and third air species barriers exhibit a lower oxygen transmission rate than said second air species barrier under the same conditions.

According to one embodiment, said device includes a first plastic support film supporting said stack of layers, and wherein said second air species barrier is located between said first plastic support film and said stack of layers.

According to one embodiment, said second air species barrier comprises a hydrophobic organic polymer.

According to one embodiment, said stack of layers comprises a top conductor pattern, and wherein said third air species barrier layer is located between said top conductor pattern and said liquid crystal material.

According to one embodiment, said third air species barrier comprises one or more layers of one or more inorganic insulator compounds.

According to one embodiment, said one or more layers of one or more inorganic compounds are deposited by sputtering or atomic layer deposition.

According to one embodiment, said liquid crystal material is located between said stack of layers and a second plastic support film, and said first air species barrier is located between said second plastic support film and said liquid crystal material.

According to one embodiment, said first air species barrier comprises one or more layers of one or more inorganic insulator compounds.

According to one embodiment, said one or more layers are deposited by sputtering or atomic layer deposition.

According to one embodiment, said first, second and third air species barriers all exhibit a water vapour transmission rate of less than 0.1 g m⁻² day⁻¹.

According to one embodiment, said first and third air species barriers both exhibit a lower oxygen transmission rate than said second air species barrier.

Using a combination of air species barriers exhibiting different transmission rates (as measured under the same conditions) in the LCD device facilitates individual tailoring of the protection against air species for each of the LC material and the organic polymer semiconductor. For example, if the organic polymer semiconductor is a polymer material whose performance over time is better in the presence of elemental oxygen, the above-described technique facilitates protecting both the LC material and the organic polymer semiconductor against moisture, while allowing more elemental oxygen in air to access the organic polymer semiconductor than the LC material.

The term “air species barrier” refers to a barrier against the transmission of one or more air species. In one embodiment, the air species barrier is a barrier that has no essential electrical or optical function within the LCD device.

Embodiments of the invention are described in detail hereunder, by way of example only, with reference to the accompanying drawings, in which:

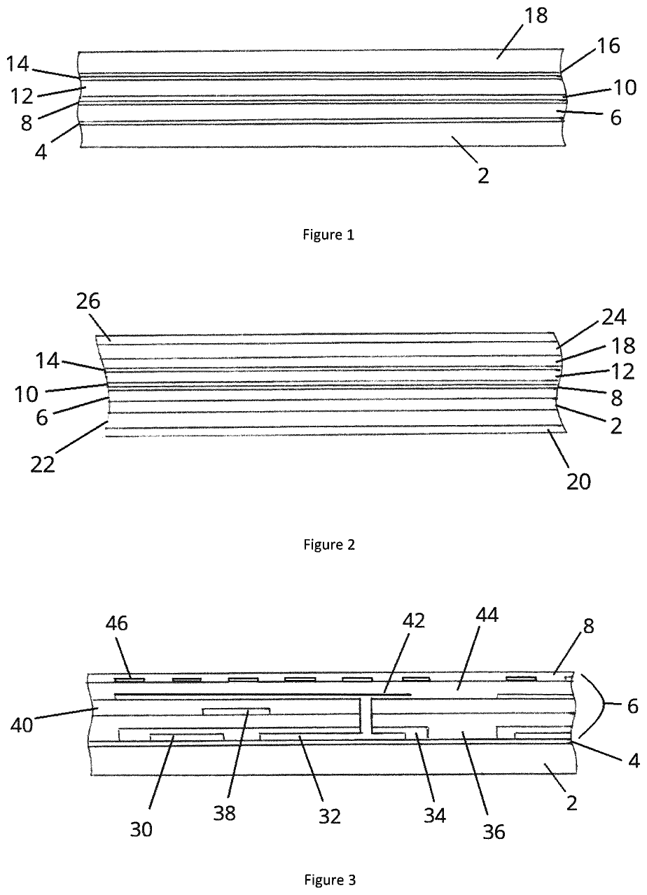

FIG. 1 shows a first embodiment according to the present invention;

FIG. 2 shows a second embodiment according to the present invention; and

FIG. 3 shows one example of an architecture for the stack of layers defining electrical control circuitry in FIGS. 1 and 2.

The embodiments described below are for the example of producing an organic liquid crystal display (OLCD) device, which comprises an organic transistor device (organic thin film transistor (OTFT) device) for the control component. OTFTs comprise an organic semiconductor (such as e.g. an organic polymer or small-molecule semiconductor) for the semiconductor channels.

The first embodiment described in detail below involves locating outer moisture barriers within the module to which orthogonal polarisers are later applied. However, the outer moisture barriers are not limited to these locations. For example, the outer moisture barriers may be provided outside of the orthogonal polarisers, as in the embodiment illustrated in FIG. 2; and this may be preferable for achieving the best optical performance from the liquid crystal display device.

Also, in this first embodiment, the formation of some of the moisture barriers involves the chemical vapour deposition (e.g. sputtering, atomic layer deposition) of inorganic compounds as part of the production process. However, in other embodiments, the formation of these moisture barriers may involve the lamination of pre-prepared moisture barrier films including one or more layers of inorganic compounds deposited by chemical vapour deposition over a plastic support film.

With reference to FIG. 1, a first embodiment comprises an organic plastic support film 2 (such as e.g. triacetate cellulose (TAC)) to which is laminated a moisture barrier film 4.

The polymer moisture barrier film 4 exhibits a WVTR of no more than about 0.1 g m⁻² day⁻¹, while exhibiting a relatively high oxygen transmission rate higher than the other two moisture barriers mentioned below, which as discussed below facilitates exposing the organic polymer semiconductor (discussed below) to elemental oxygen from external air, particularly in the TFT channel regions, discussed below.

Examples of moisture barrier films exhibiting low WVTR while exhibiting a relatively high oxygen transmission rate are hydrophobic organic polymer films whose chemical composition repels water but whose relatively low packing density (fraction of unit volume occupied by constituent particles, i.e. polymer molecules in the case of a polymer)) is sufficiently low to offer substantially no resistance to the transmission of molecular oxygen. One specific example of a hydrophobic polymer barrier film is a fluoropolymer barrier film such as e.g. a Hydroblock® P-series TR film made by Honeywell International Inc. The moisture barrier film 4 does not include any vapour-deposited inorganic layer (of the kind used in the other moisture barriers mentioned below) whose relatively high packing density would reduce the oxygen transmission rate.

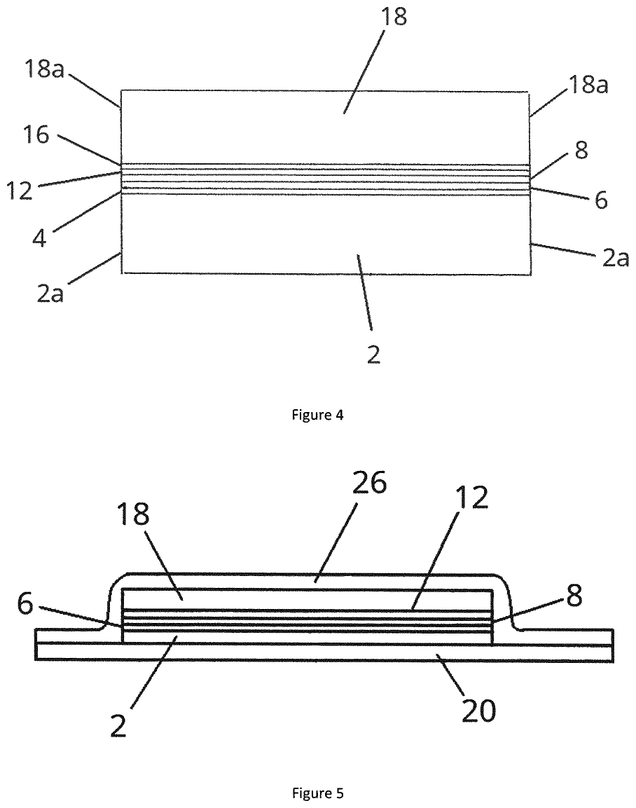

In this embodiment, fluoropolymer barrier film 4 plays no essential electrical or optical function in the LCD device; it is included solely for its barrier function. The fluoropolymer barrier film 4 is laminated continuously over at least the whole area of the plastic support film that remains in the product device (after any trimming process etc.), as shown in FIG. 4, where 2a indicates the edges of the plastic support film in the product LCD device. The fluoropolymer barrier film 4 is not subject to any patterning process within this area, such that the fluoropolymer barrier film 4 does not include any intentional holes within this area. For conciseness, FIG. 4 only shows those elements necessary to illustrate the different positions of the three barriers 4, 8, 16 in relation to the LC material 12 and the stack 6 including one or more organic polymer semiconductor layers.

The working surface (upper surface in FIG. 1) of the moisture barrier film 4 is coated with an organic planarization layer or otherwise treated to provide a working surface better suited to the formation of an intricate conductor pattern on the moisture barrier film 4.

Next, a stack of layers 6 defining active matrix circuitry for controlling the degree to which the liquid crystal material in each pixel region rotates the polarisation of light, is formed over the moisture barrier film 4. As discussed below in relation to FIG. 3, the uppermost layer of this stack of layers 6 may be a conductor pattern, such as a common conductor pattern 46 for a fringe-field-switching (FFS) type LCD device.

Over the top conductor pattern 46 is formed a layer 8 of an inorganic compound such as e.g. aluminium nitride by chemical vapour deposition (e.g. sputtering, ALD). In addition to a low WVTR (no higher than about 0.1 g m⁻² day⁻¹, this layer also exhibits a lower OTR than the moisture barrier film 4 mentioned above, and additionally protects the overlying liquid crystal material against the ingress of elemental oxygen via the stack of layers 6.

In this embodiment, inorganic barrier layer 8 plays no essential electrical or optical function in the LCD device; it is included solely for its barrier function. This inorganic layer 8 is also formed continuously over at least the whole area of the plastic support film 2 that remains in the product device (after any trimming process etc.), as shown in FIG. 4, where 2a indicates the edges of the plastic support film in the product LCD device. The inorganic layer 8 is also not subject to any patterning process within this area, such that the inorganic layer 4 does not include any intentional holes within this area.

Over this barrier layer 8 is formed an alignment layer 10, which (together with the alignment layer 14 on the opposite side of the LC material) functions to retain the LC material in the desired state (in relation to how it rotates the polarisation of light) when no additional electrical field is electrically generated within the LC material via the control circuitry defined by the stack of layers 6. A rubbed organic polymer layer such as a rubbed polyimide layer is one example of an LC alignment layer.

Separately, another layer 16 of an inorganic compound is formed by chemical vapour deposition (e.g. sputtering, ALD) on another organic plastic support film 18 (e.g. TAC), whose working surface (bottom surface in FIG. 1) may be coated with a planarization layer or otherwise treated to facilitate the formation thereon of the inorganic barrier layer 16. This inorganic layer exhibits both a low WVTR (no higher than about 0.1 g m⁻² day⁻¹) and a lower OTR than the moisture barrier film 4 on which the above-described stack of layers 6 is formed. In the assembly shown in FIG. 1, this inorganic layer 16 protects the liquid crystal material against the ingress of inorganic barrier layer 16 plays no essential electrical or optical function in the LCD device; it is included solely for its barrier function. This inorganic layer 16 is formed continuously over at least the whole area of the plastic support film 18 that remains in the product device (after any trimming process etc.), as shown in FIG. 4, where 2a indicates the edges of the plastic support film in the product LCD device. The inorganic layer 16 is not subject to any patterning process within this area, such that the inorganic layer 16 does not include any intentional holes within this area.

The second alignment layer 14 (e.g. rubbed organic polymer layer such a rubbed polyimide layer) is formed over the inorganic barrier layer 16, and then this unit is laminated to the unit comprising the first alignment layer 10 via a precisely controlled thickness of liquid crystal material 12, to produce a liquid crystal cell. The thickness of liquid crystal material is controlled by spacers (not shown). The spacers may, for example, comprise substantially spherical structures that are not an integral part of the either the two units laminated together or may be defined by the topographical surface profile of one or both of the units laminated together.

The lamination may, for example, comprise a roll-to-roll lamination technique in which a carefully controlled volume of liquid crystal material deposited in one or more locations is spread over at least the whole of the display area by the action of laminating the two units together. Alternatively, the lamination may, for example, comprise first laminating the units together and then introducing the liquid crystal material into the space between the two units.

Orthogonal, linear polariser films (not shown) are then applied to opposite sides of the liquid crystal cell. The polariser films may each comprise a thin layer of iodine-doped polyvinylalcohol (PVA) supported on a thicker organic plastic support film. Stretching of the thin layer of iodine-doped PVA causes the PVA chains to align in one direction.

In an alternative embodiment shown in FIG. 2, the outer barriers 4, 16 in the embodiment of FIG. 1 are replaced by barriers on the outside of the polarisation films 22, 24. A moisture barrier film 20 of the kind laminated to the plastic support film 2 in the embodiment of FIG. 1, and an encapsulation film 26, comprising one or more inorganic layers deposited by chemical vapour deposition over a plastic support film, are laminated to opposite sides of the unit comprising the liquid crystal cell and the orthogonal, linear polarisation sheets 22, 24, such that the moisture barrier film (having the higher oxygen transmission rate) is on the opposite side of the stack 6 to the LC material 12. It is also a feature of this alternative embodiment that the outer barriers 20, 26 extend continuously over the whole area of the plastic support films 2, 18 in the product device, as shown in FIG. 5; the outer barriers 20, 26 are not subject to any patterning in this area, and do not include any intentional holes in this area. As shown in FIG. 5 the outer barriers 20, 26 extend continuously over the whole area of the plastic support films 2, 8 in the product device, and are joined by sealant (now shown) beyond the edges of the area of the plastic support films 2, 8. For conciseness, FIG. 5 also only shows those elements necessary to illustrate the different positions of the three moisture barriers 8, 20, 26 in relation to the LC material 12 and the stack 6 including one or more organic polymer semiconductor layers.

One example of an architecture for the stack of layers 6 in FIGS. 1 and 2 is shown in FIG. 3, for the example of a FFS-type LCD device. The stack of layers 6 may have a different TFT architecture, and/or may be designed for a different type of LCD device, but the stack of layers 6 is characterised in this embodiment by the inclusion of an organic polymer semiconductor, whose performance over time (as measured by the change over time in threshold voltage for the TFTs) is improved by exposure to elemental oxygen in the absence of moisture.

Over the fluoropolymer barrier film 4 (or plastic support film 2 in the alternative embodiment of FIG. 2) is formed a first conductor pattern (e.g. a metal pattern), which defines source and drain conductors 30, 32 for an array of thin-film transistors (TFTs). Each source conductor provides the source electrodes for a row of TFTs, and extends to a location outside the display area for connection to a respective terminal of a driver chip. Next, an organic polymer semiconductor pattern 34 is formed to provide semiconductor channels in the regions where the source and drain conductors for each TFT are closest. Before forming the organic semiconductor pattern, the surface of the first conductor pattern may be treated to tune the work-function of the conductor pattern to improve the efficiency of charge-injection from the conductor pattern into the organic semiconductor. The surface treatment may, for example, comprise forming a self-assembled monolayer (SAM) of a suitable organic material.

An organic gate dielectric 36 (comprising one or more organic insulating, dielectric layers) is formed over the semiconductor pattern 4. A second conductor pattern (e.g. metal pattern) is formed over the gate dielectric 36, and defines an array of gate conductors (e.g. gate lines), each gate conductor providing the gate electrode for a respective column of TFTs, whereby each TFT (pixel) is associated with a respective unique combination of source and gate conductors.

Over the second conductor pattern is formed a further, organic insulator (comprising one or more organic insulating layers) 40; and the resulting structure is patterned (by e.g. etching through a photoresist mask) to at least define vias extending down to each of the drain conductors. A third conductor pattern (e.g. metal pattern) is formed over the insulator 40, and defines an array of pixel conductors 42, each pixel conductor in electrical contact with a respective drain conductor 32. Another organic dielectric (comprising one or more organic dielectric layers) 44 is formed over the third conductor pattern, and a fourth conductor pattern (e.g. metal pattern) is formed over the dielectric 44. The fourth conductor pattern defines the common conductor pattern for each pixel in the FFS-type LCD device; the pixel electrode 42 and common conductor pattern 46 for a pixel region are configured such that an electric potential difference between the two can induce a change in the state of the LC material in that pixel region (in relation to how the LC material rotates the polarisation of light).

In the above-described stack of layers from the first conductor pattern defining the source/drain conductors to the conductor pattern defining the common conductor pattern 46, all of the layers are either patterned and/or comprise organic materials. In contrast, the inorganic, barrier layers 4, 8, 16 (or encapsulation films 20, 26) are all unpatterned in at least the whole area of the plastic support films 2, 18 that remain in the product device (after e.g. any trimming process etc.), and each have lower WVTR than any of the layers of this stack, and moreover have a lower WVTR than any of the plastic support films 2, 18, alignment layers 10, 14, and polariser films 22, 24.

In addition to any modifications explicitly mentioned above, it will be evident to a person skilled in the art that various other modifications of the described embodiment may be made within the scope of the invention.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features.

1. A device, comprising:
a liquid crystal cell comprising liquid crystal material;
a stack of layers, including one or more organic polymer semiconductor layers, for electrically controlling one or more optical properties of the liquid crystal material;
first and second air species barriers between which both the liquid crystal material and the one or more organic polymer semiconductor layers are located; and
a third air species barrier between the liquid crystal material and the one or more organic polymer semiconductor layers; wherein the first and second air species barriers exhibit substantially different transmission rates under the same conditions for at least one air species.

2. The device according to claim 1, wherein the liquid crystal material is located between the first and third air species barriers, and wherein the first and third air species barriers exhibit a lower oxygen transmission rate than the second air species barrier under the same conditions.

3. The device, according to claim 1, wherein the device includes a first plastic support film supporting the stack of layers, and wherein the second air species barrier is located between the first plastic support film and the stack of layers.

4. The device according to claim 3, wherein the second air species barrier comprises a hydrophobic organic polymer.

5. The device according to claim 1, wherein the stack of layers comprises a top conductor pattern, and wherein the third air species barrier layer is located between the top conductor pattern and the liquid crystal material.

6. The device according to claim 5, wherein the third air species barrier comprises one or more layers of one or more inorganic insulator compounds.

7. The device according to claim 6, wherein the one or more layers of one or more inorganic compounds are deposited by sputtering or atomic layer deposition.

8. The device according to claim 1, wherein the liquid crystal material is located between the stack of layers and a second plastic support film, and the first air species barrier is located between the second plastic support film and the liquid crystal material.

9. The device according to claim 8, wherein the first air species barrier comprises one or more layers of one or more inorganic insulator compounds.

10. The device according to claim 9, wherein the one or more layers are deposited by sputtering or atomic layer deposition.

11. The device according to claim 1, wherein the first, second and third air species barriers all exhibit a water vapour transmission rate of less than 0.1 g m⁻² day⁻¹.

12. The device according to claim 2, wherein the first and third air species barriers both exhibit a lower oxygen transmission rate than the second air species barrier.
